(19) United States
(12) Patent Application Publication
(10) Pub. No.: US 2026/0268950 A1
(43) Pub. Date: Sep. 10, 2026

(54) SEMICONDUCTOR INTEGRATED CIRCUIT AND SEMICONDUCTOR STORAGE DEVICE

(71) Applicant: Kioxia Corporation, Tokyo (JP)

(72) Inventor: Yasuaki ISSHIKI, Kawasaki (JP)

(21) Appl. No.: 19/314,134

(22) Filed: Aug. 29, 2025

(30) Foreign Application Priority Data
Mar. 10, 2025 (JP) 2025-037471

(51) Int. Cl. G11C 7/10; G11C 16/10; H10D 84/80; H10D 89/60

(52) U.S. Cl. CPC G11C 7/1048; H10D 84/811; H10D 89/611; G11C 16/10

(57) ABSTRACT

According to one embodiment, a semiconductor integrated circuit includes: a first transmission line; a first switch connected between a first node and a second node in the first transmission line; a second transmission line; a second switch connected between a third node and a fourth node in the second transmission line; a voltage follower including an inversion input terminal, a non-inversion input terminal, and an output terminal; a first resistor connected between the non-inversion input terminal of the voltage follower and the first node; a second resistor connected between the non-inversion input terminal of the voltage follower and the third node; a third switch connected between the output terminal of the voltage follower and the second node; a fourth switch connected between the output terminal of the voltage follower and the fourth node; and a fifth switch connected between the second node and the fourth node.

### CROSS-REFERENCE TO RELATED APPLICATION

This application is based upon and claims the benefit of priority from Japanese Patent Application No. 2025-037471, filed Mar. 10, 2025, the entire contents of which are incorporated herein by reference.

### FIELD

Embodiments described herein relate generally to a semiconductor integrated circuit and a semiconductor storage device.

### BACKGROUND

For example, as high-speed differential serial transmission schemes, equalizers are provided on receiver sides.

Equalizers adjust signals to optimize frequency characteristics of received signals.

### DESCRIPTION OF THE DRAWINGS

FIG. 1 is a block diagram illustrating a configuration of a memory system including a semiconductor integrated circuit according to a first embodiment;

FIG. 2 is a block diagram illustrating a circuit configuration of a semiconductor memory according to the first embodiment;

FIG. 3 is a block diagram illustrating a configuration of the semiconductor integrated circuit according to the first embodiment;

FIG. 4 is a circuit diagram illustrating configurations of a shaping protection circuit and a data selector in the semiconductor integrated circuit according to the first embodiment; and

FIGS. 5A and 5B are circuit diagrams illustrating configurations of switches inside the data selector according to a second embodiment.

### DETAILED DESCRIPTION

Embodiments provide a semiconductor integrated circuit and a semiconductor storage device capable of improving performance of an operation.

In general, according to one embodiment, a semiconductor integrated circuit includes: a first transmission line (e.g., path from T1P to T2P); a first switch (e.g., S3P) connected between a first node (e.g., N1P) and a second node (e.g., N2P) in the first transmission line; a second transmission line (e.g., path from T1N to T2N); a second switch (e.g., S3N) connected between a third node (e.g., N1N) and a fourth node (e.g., N2N) in the second transmission line; a voltage follower (e.g., VF) including an inversion input terminal, a non-inversion input terminal, and an output terminal; a first resistor (e.g., R2P) connected between the non-inversion input terminal of the voltage follower and the first node; a second resistor (e.g., R2N) connected between the non-inversion input terminal of the voltage follower and the third node; a third switch (e.g., S1P) connected between the output terminal of the voltage follower and the second node; a fourth switch (e.g., S1N) connected between the output terminal of the voltage follower and the fourth node; and a fifth switch (e.g., S2) connected between the second node and the fourth node.

Hereinafter, embodiments will be described with reference to the drawings. In the following description, elements that have the same functions and configurations are denoted by common reference numerals. In the following embodiments, devices and methods for embodying technical sprits of the embodiments are exemplary, and materials, shapes, structures, arrangement, and the like of the elements do not specify the followings.

Functional blocks can be implemented by one of hardware and computer software or combination of both. It is not essential for the functional blocks to be distinguished as in the following examples. For example, some functions may be executed by a functional block different from the illustrated functional blocks. Further, the illustrated functional blocks may be further divided into finer functional sub-blocks.

A semiconductor integrated circuit according to embodiments to be described here is, for example, a circuit in an equalizer provided on a receiver side in an electronic device. An equalizer is provided in a host interface circuit inside a memory controller that transmits and receives a signal to and from a host device. Here, an equalizer provided in the host interface circuit will be described as an example.

### 1. First Embodiment

A semiconductor integrated circuit according to a first embodiment will be described. The semiconductor integrated circuit is mounted on a host interface circuit inside a memory controller in a memory system including the memory controller and a semiconductor memory.

### 1.1. Configuration in First Embodiment

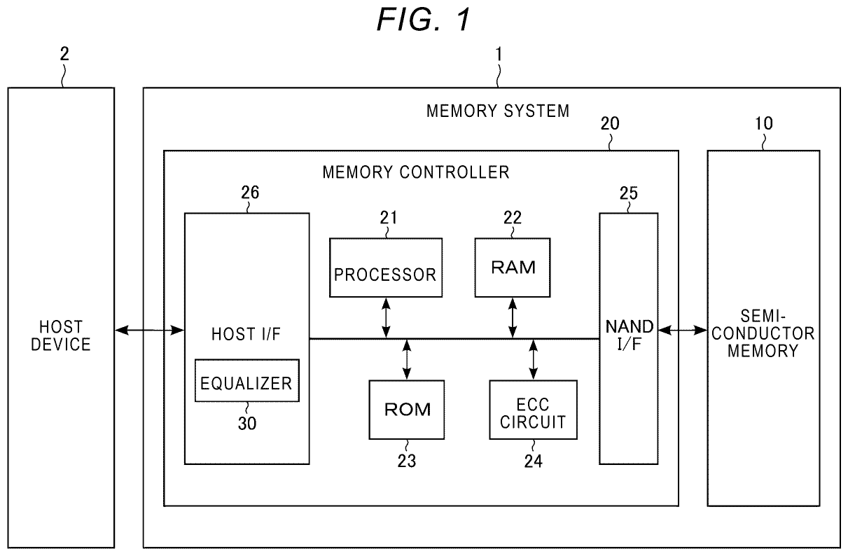

First, the memory system including the semiconductor integrated circuit according to the first embodiment will be described with reference to FIG. 1. FIG. 1 is a block diagram illustrating a configuration of the memory system including the semiconductor integrated circuit according to the first embodiment. A memory system 1 is connected to an external host device 2 and can execute various operations in response to commands from the host device 2. The memory system 1 includes a semiconductor memory 10 and a memory controller 20.

The semiconductor memory (or a nonvolatile memory) 10 includes, for example, a NAND flash memory in which memory cells (also referred to as memory cell transistors) are arrayed 2-dimensionally or 3-dimensionally and stores data in a nonvolatile manner. The details of the semiconductor memory 10 will be described below.

The memory controller 20 is connected to the semiconductor memory 10 via a NAND bus. The memory controller 20 controls the semiconductor memory 10. The NAND bus transmits and receives signals in conformity with a NAND interface. The memory controller 20 is connected to the host device 2 via a host bus. The memory controller 20 accesses the semiconductor memory 10 in response to a command received from the host device 2. The host bus transmits and receives signals in conformity with a host interface.

For example, the semiconductor memory 10 and the memory controller 20 described above may be combined to configure a single semiconductor device. Examples of such a semiconductor device include a memory card including an SD™ card and a solid state drive (SSD). The memory controller 20 may be, for example, a system-on-a-chip (SoC) or the like.

The host device 2 is, for example, a personal computer, a portable terminal such as a smartphone, or a digital camera. The host bus is, for example, a bus in conformity with an SD^{TM} interface.

### 1.1.1 Semiconductor Memory

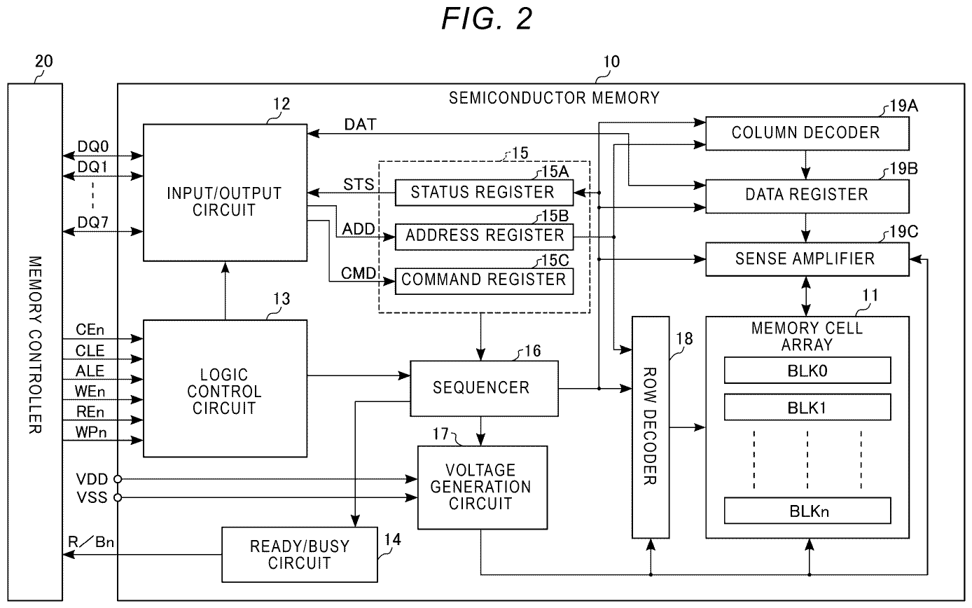

The semiconductor memory 10 in the memory system 1 will be described. First, a circuit configuration of the semiconductor memory 10 will be described. FIG. 2 is a block diagram illustrating a circuit configuration of a semiconductor memory according to the first embodiment.

The semiconductor memory 10 includes a memory cell array 11, an input/output circuit 12, a logic control circuit 13, a ready/busy circuit 14, a register group 15, a sequencer (or a control circuit) 16, a voltage generation circuit 17, a row decoder 18, a column decoder 19A, a data register 19B, and a sense amplifier 19C. The register group 15 includes a status register 15A, an address register 15B, and a command register 15C.

The memory cell array 11 includes one block or a plurality of blocks BLK0, BLK1, BLK2, . . . , and BLKn (where n is an integer of 0 or more). Each of the plurality of blocks BLK 0 to BLKn includes a plurality of memory cell transistors (hereinafter also referred to as memory cells) associated with rows and columns. The memory cell transistor is a nonvolatile memory cell capable of electrical erasing and programming. The memory cell array 11 includes a plurality of word lines, a plurality of bit lines, and a source lines for applying voltages to the memory cell transistors. A specific configuration of the block BLKn will be described below.

The input/output circuit 12 and the logic control circuit 13 are connected to the memory controller 20 via input/output terminals (or NAND buses). The input/output circuit 12 transmits and receives I/O signals DQ (for example, DQ0, DQ1, DQ2, . . . , and DQ7) to and from the memory controller 20 via the input/output terminals. The I/O signals DQ are used for communication of commands, addresses, data, and the like.

The logic control circuit 13 receives external control signals from the memory controller 20 via an input/output terminal (or a NAND bus). Examples of the external control signals include, a chip enable signal CEn, a command latch enable signal CLE, an address latch enable signal ALE, a write enable signal WEn, a read enable signal REn, and a write protect signal WPn. “n” suffixed to a signal name indicates that the signal is active row.

The chip enable signal CEn enables the semiconductor memory 10 to be selected when the plurality of semiconductor memories 10 are mounted, and is asserted when the semiconductor memory 10 is selected. The command latch enable signal CLE enables a command transmitted as a signal DQ to be latched in the command register 15C. The address latch enable signal ALE enables an address transmitted as a signal DQ to be latched in the address register 15B. The write enable signal WEn enables data transmitted as a signal DQ to be stored in the input/output circuit 12. The read enable signal REn enables data read from the memory cell array 11 to be output as a signal DQ. The write protect signal WPn is asserted when a write operation and an erasing operation on the semiconductor memory 10 are prohibited.

The ready/busy circuit 14 generates a ready/busy signal R/Bn under the control of the sequencer 16. The ready/busy signal R/Bn indicates whether the semiconductor memory 10 is in a ready state or a busy state. The ready state indicates that the semiconductor memory 10 is in a state where a command from the memory controller 20 is receivable. The busy state indicates that the semiconductor memory 10 is in a state where a command from the memory controller 20 is not receivable. The memory controller 20 can ascertain whether the semiconductor memory 10 is in the ready state or the busy state by receiving the ready/busy signal R/Bn from the semiconductor memory 10.

The status register 15A stores status information STS necessary for an operation of the semiconductor memory 10. The status register 15A transmits the status information STS to the input/output circuit 12 in response to an instruction from the sequencer 16.

The address register 15B stores an address ADD transmitted from the input/output circuit 12. The address ADD includes a row address and a column address. The row address includes, for example, a block address for designating an operation target block BLKn and a page address for designating an operation target word line WL in the designated block.

The command register 15C stores a command CMD transmitted from the input/output circuit 12. The command CMD includes, for example, a write command to instruct the sequencer 16 to execute a write operation, a read command to instruct the sequencer 16 to execute a read operation, and an erasing command to instruct the sequencer 16 to execute an erasing operation.

For the status register 15A, the address register 15B, and the command register 15C, for example, a static random access memory (SRAM) is used.

The sequencer 16 receives a command from the command register 15C and generally controls the semiconductor memory 10 in accordance with a sequence that is based on the command.

The sequencer 16 executes a write operation, a read operation, and an erasing operation by controlling the voltage generation circuit 17, the row decoder 18, the column decoder 19A, the data register 19B, the sense amplifier 19C, and the like. Specifically, the sequencer 16 writes data into a plurality of memory cell transistors designated with the address ADD by controlling the voltage generation circuit 17, the row decoder 18, the data register 19B, and the sense amplifier 19C based on a write command received from the command register 15C. The sequencer 16 reads data from a plurality of memory cell transistors designated with the address ADD by controlling the voltage generation circuit 17, the row decoder 18, the column decoder 19A, the data register 19B, and the sense amplifier 19C based on a read command received from the command register 15C. The sequencer 16 erases data stored in a block designated with the address ADD by controlling the voltage generation circuit 17, the row decoder 18, the column decoder 19A, the data register 19B, and the sense amplifier 19C based on an erasing command received from the command register 15C. A circuit that includes the column decoder 19A and the data register 19B is referred to as a column-based control circuit.

The voltage generation circuit 17 receives a supply voltage VDD and a ground voltage VSS (or GND) via a power supply terminal from the outside of the semiconductor memory 10. The supply voltage VDD is an outside voltage supplied from the outside of the semiconductor memory 10. The ground voltage VSS is an outside voltage supplied from the outside of the semiconductor memory 10 and is, for example, 0 V.

The voltage generation circuit 17 generates a plurality of voltages necessary for a write operation, a read operation, and an erasing operation using the supply voltage VDD. The voltage generation circuit 17 supplies the generated voltages to the memory cell array 11, the row decoder 18, and the sense amplifier 19C.

The row decoder 18 receives a row address from the address register 15B and decodes the row address. The row decoder 18 selects any of a plurality of blocks based on a decoding result of the row address and further selects a word line WL inside the selected block BLKn. Further, the row decoder 18 transmits a plurality of voltages supplied from the voltage generation circuit 17 to the selected block BLKn.

The column decoder 19A receives a column address from the address register 15B and decodes the column address. The column decoder 19A selects a latch circuit inside the data register 19B based on a decoding result of the column address.

The data register 19B includes a plurality of latch circuits. The latch circuit temporarily stores write data and read data.

The sense amplifier 19C senses and amplifies data read from a memory cell transistor to a bit line during a read operation for the data. Further, the sense amplifier 19C temporarily stores read data DAT read from the memory cell transistor and transmits the stored read data DAT to the data register 19B. The sense amplifier 19C temporarily stores the write data DAT transmitted from the input/output circuit 12 via the data register 19B during a write operation for the data. Further, the sense amplifier 19C transmits the write data DAT to a bit line.

### 1.1.2. Memory Controller

Next, a configuration of the memory controller 20 will be described with reference to FIG. 1. The memory controller 20 includes a processor 21, a random access memory (RAM) 22, a read only memory (ROM) 23, an error checking and correction (ECC) circuit 24, a NAND interface circuit (NAND I/F) 25, and a host interface circuit (host I/F) 26.

The processor 21 controls an overall operation of the memory controller 20. For example, when a write command is received from the host device 2, the processor 21 issues a write command to the NAND interface circuit 25 in response to the received write command. When a read command and an erasing command are received, the processor 21 issues a read command and an erasing command to the NAND interface circuit 25 in response to the received read command and erasing command.

The processor 21 executes various processes such as wear leveling for managing the semiconductor memory 10. An operation of the memory controller 20 to be described below may be implemented by causing the processor 21 to execute software or firmware or may be implemented by hardware. The processor 21 includes, for example, a central processing unit (CPU).

The RAM 22 is used as a work area of the processor 21. The RAM 22 temporarily stores firmware for managing the semiconductor memory 10, various management tables such as logical-to-physical address conversion table, and data.

The RAM 22 stores, for example, user data received from the host device 2, data processed by the ECC circuit 24, and write data to be written into the semiconductor memory 10. The RAM 22 stores read data received from the semiconductor memory 10 and data to be transmitted to the host device 2.

The RAM 22 is a volatile memory. The RAM 22 is, for example, a semiconductor memory such as a dynamic random access memory (DRAM) or static random access memory (SRAM).

The ROM 23 stores, for example, software or firmware to be executed by the processor 21 and various parameters necessary for execution of the processor 21. The ROM 23 is a nonvolatile memory. The ROM 23 is, for example, an electrically erasable programmable read only memory (EEPROM^{TM}).

The ECC circuit 24 executes a process related to data error correction. The ECC circuit 24 executes a process related to error detection and correction on data written on the semiconductor memory 10 and data read from the semiconductor memory 10. Specifically, during a write operation, the ECC circuit 24 generates a parity based on write data written on the semiconductor memory 10 and assigns the generated parity to the write data. During a read operation, the ECC circuit 24 generates a syndrome based on read data received from the semiconductor memory 10 and detects and corrects an error of the read data based on the generated syndrome.

The NAND interface circuit 25 is connected to the semiconductor memory 10 via the NAND bus and is responsible for communication with the semiconductor memory 10. The NAND interface circuit 25 transmits various signals, commands, and data to the semiconductor memory 10 based on the command received from the processor 21. The NAND interface circuit 25 receives various signals and data from the semiconductor memory 10.

The host interface circuit 26 is connected to the host device 2 via the host bus and is responsible for communication with the host device 2. The host interface circuit 26 transmits a command and data received from the host device 2 to the processor 21 and the RAM 22, respectively. The host interface circuit 26 transmits data inside the RAM 22 to the host device 2 in response to a command from the processor 21.

The host interface circuit 26 includes an equalizer 30. The equalizer 30 is a compensation circuit in which a signal is adjusted by a filter circuit or the like to optimize frequency characteristics of a signal received from the host device 2.

### 1.1.3. Equalizer

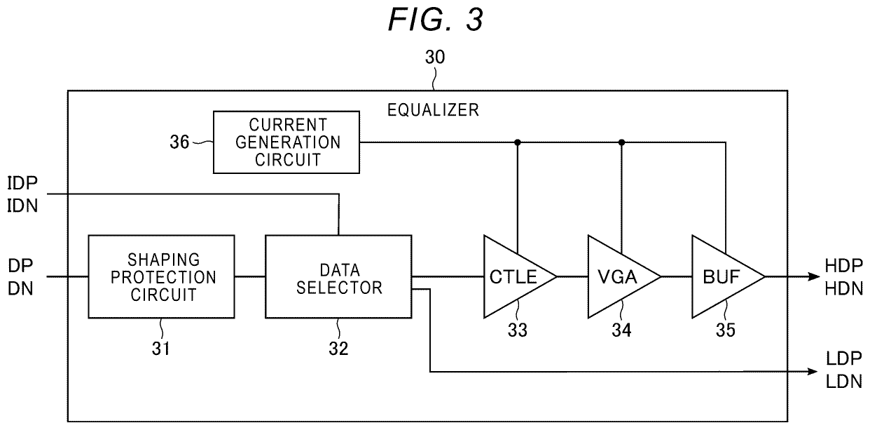

Hereinafter, the equalizer 30 serving as the semiconductor integrated circuit according to the first embodiment will be described with reference to FIG. 3. FIG. 3 is a block diagram illustrating a configuration of the equalizer 30 serving as the semiconductor integrated circuit according to the first embodiment.

The equalizer 30 includes a shaping protection circuit 31, a data selector 32, a linear equivalent circuit 33, a variable gain amplifier circuit 34, a buffer circuit 35, and a current generation circuit (or a voltage generation circuit) 36.

The shaping protection circuit 31 includes, for example, a T coil circuit, an electrostatic protection circuit, and a termination resistor. The T coil circuit controls a frequency response of a received signal using an inductor. For example, a waveform of a signal received from the host device 2 is shaped. The electrostatic protection circuit blocks flow of an abnormal voltage such as electrostatic discharge to a circuit element inside the equalizer 30 to prevent the equalizer 30 from being destructed. The termination resistor is a resistor connected to termination of a transmission line and curbs reflection of a received signal occurring due to mismatch of the impedance by matching characteristic impedance and a resistant value of the transmission line. Accordingly, quality of the received signal is improved.

The data selector 32 selects one of a path for a high-speed signal or a path for a low-speed signal and outputs a received signal or a test signal.

The linear equivalent circuit 33 is a circuit that compensates for attenuation of a frequency response occurring in the transmission line. Accordingly, quality of an input signal is improved. The linear equivalent circuit 33 includes, for example, a continuous time linear equivalent circuit (continuous time linear equalizer (CTLE)).

The variable gain amplifier circuit (variable gain amplifier (VGA)) 34 is an amplifier circuit that can adjust a gain and amplifies a level of an input signal in accordance with characteristics of a transmission line or a frequency or intensity of a signal.

The buffer circuit 35 buffers a signal, that is, amplifies a level of a signal, so that a circuit at the rear stage can receive the signal accurately.

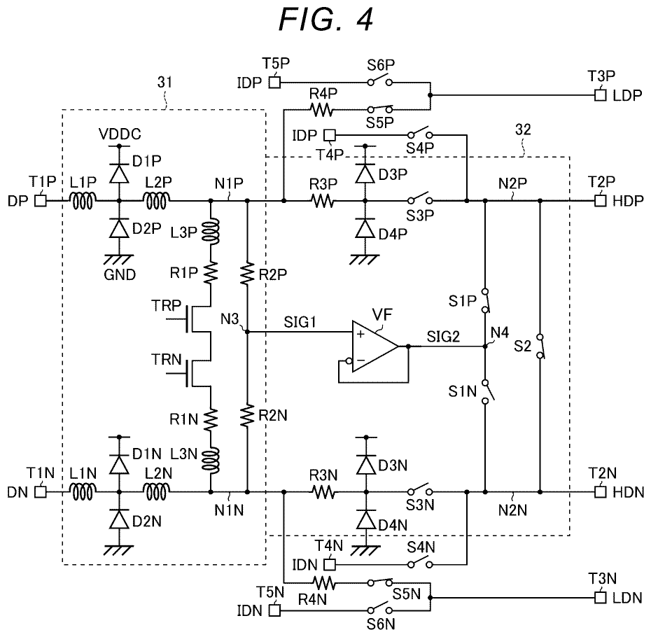

Hereinafter, examples of detailed circuits of the shaping protection circuit 31 and the data selector 32 will be described. FIG. 4 is a circuit diagram illustrating configurations of the shaping protection circuit 31 and the data selector 32 in the equalizer 30 according to the first embodiment. In a dotted enclosure illustrated in FIG. 4, circuit elements in the shaping protection circuit 31 and the data selector 32 are simply categorized, but it does not limit the circuit elements in each circuit. Operations related to test signals IDP and IDN and output signals LDP and LDN will not be described.

In the circuits illustrated in FIG. 4, the shaping protection circuit 31 and the data selector 32 in the equalizer 30 are illustrated. The shaping protection circuit 31 and the data selector 32 include, as circuit elements, inductors L1P, L2P, L3P, L1N, L2N, and L3N, diodes D1P, D2P, D3P, D4P, D1N, D2N, D3N, and D4N, resistors R1P, R2P, R3P, R4P, R1N, R2N, R3N, and R4N, transistors TRP and TRN, a voltage follower VF, switches S1P, S2P, S3P, S4P, S5P, S6P, S1N, S3N, S4N, S5N, and S6N.

Each of the transistors TRP and TRN is, for example, an n-channel metal oxide semiconductor (MOS) field effect transistor. The voltage follower VF includes an arithmetic amplifier that includes a non-inversion input terminal (positive input terminal), an inversion input terminal (negative input terminal), and an output terminal. The output terminal of the arithmetic amplifier is connected to the inversion input terminal.

The shaping protection circuit 31 includes the T coil circuit, the electrostatic protection circuit, and the termination resistor, as described above. The T coil circuit includes, for example, the inductors L1P, L2P, L3P, L1N, L2N, and L3N. The electrostatic protection circuit includes, for example, the diodes D1P, D2P, D1N, and D2N. The termination resistors include, for example, the resistors R1P, R2P, R1N, and R2N.

Hereinafter, connection of the circuit elements in the shaping protection circuit 31 and the data selector 32 will be described.

In a transmission line (or a signal line) from an input terminal T1P to an output terminal T2P, the input terminal T1P is connected to the output terminal T2P via the inductor L1P, the diodes D1P and D2P, the inductor L2P, the resistor R3P, the diodes D3P and D4P, and the switch S3P.

The diode D1P is connected between a node supplied with the supply voltage VDDC (hereinafter referred to as a supply voltage VDDC node) and a node between the inductors L1P and L2P. The diode D2P is connected between a node supplied with the ground voltage GND (hereinafter referred to as a ground voltage GND node) and the node between the inductors L1P and L2P. The diodes D1P and D2P function as an electrostatic protection circuit.

The diode D3P is connected between the supply voltage VDDC node and a node between the resistor R3P and the switch S3P. The diode D4P is connected between the ground voltage GND node and the node between the resistor R3P and the switch S3P. The diodes D3P and D4P function as an electrostatic protection circuit.

In a transmission line (or a signal line) from the input terminal T1N to the output terminal T2N, the input terminal T1N is connected to the output terminal T2N via the inductor L1N, the diodes D1N and D2N, the inductor L2N, the resistor R3N, the diodes D3N and D4N, and the switch S3N.

The diode D1N is connected between the supply voltage VDDC node and a node between the inductors L1N and L2N. The diode D2N is connected between the ground voltage GND node and the node between the inductors L1N and L2N. The diodes D1N and D2N function as an electrostatic protection circuit.

The diode D3N is connected between the supply voltage VDDC node and a node between the resistor R3N and the switch S3N. The diode D4N is connected between the ground voltage GND node and the node between the resistor R3N and the switch S3N. The diodes D3N and D4N function as an electrostatic protection circuit.

A node between the inductors L2P and the resistor R3P is denoted by N1P and a node between the inductor L2N and the resistor R3N is denoted by N1N.

The node N1P is connected to the node N1N via the inductor L3P, the resistor R1P, the transistors TRP and TRN, the resistor R1N, and the inductor L3N. The node N1P is connected to the node N1N via the resistors R2P and R2N.

A node between the switch S3P and the output terminal T2P is denoted by N2P and a node between the switch S3N and the output terminal T2N is denoted by N2N.

The node N2P is connected to the node N2N via the switches S1P and S1N. The node N2P is also connected to the node N2N via the switch S2.

A node between the resistors R2P and R2N is denoted by N3 and a node between the switches S1P and S1N is denoted by N4.

The voltage follower VF is connected between the nodes N3 and N4. That is, a non-inversion input terminal (positive input terminal) of the voltage follower VF is connected to the node N3. An inversion input terminal (negative input terminal) of the voltage follower VF is connected to the output terminal of the voltage follower VF. The output terminal of the voltage follower VF is connected to the node N4.

The node N1P is connected to the output terminal T3P via the resistor R4P and the switch S5P. The input terminal T5P is connected to the output terminal T3P via the switch S6P. The input terminal T4P is connected to the node N2P via the switch S4P.

The node N1N is connected to the output terminal T3N via the resistor R4N and the switch S5N. The input terminal T5N is connected to the output terminal T3N via the switch S6N. The input terminal T4N is connected to the node N2N via the switch S4N.

Inductance of the inductor L1P is set to be the same as inductance of the inductor L1N. Inductance of the inductor L2P is set to be the same as inductance of the inductor L2N. Inductance of the inductor L3P is set to be the same as inductance of the inductor L3N. A resistant value of the resistor R1P is set to be the same as a resistant value of the resistor R1N. A resistant value of the resistor R2P is set to be the same as a resistant value of the resistor R2N. Further, a resistant value of the resistor R3P is set to be the same as a resistant value of the resistor R3N.

Next, an example of an operation in the shaping protection circuit 31 and the data selector 32 will be described. In the equalizer 30 inside the host interface circuit 26 of the memory controller 20, offset calibration of a direct-current signal is executed for a stall period in an M-PHY standard that is a communication standard. In the offset calibration, for example, an operation of inputting a first voltage to a first transmission line from the input terminal T1P to the output terminal T2P, inputting a second voltage to a second transmission line from the input terminal T1N to the output terminal T2N, and outputting an intermediate voltage between the first voltage and the second voltage from the first transmission line and the second transmission line is executed. Hereinafter, an operation during execution of the offset calibration will be described.

When the offset calibration is executed, the transistors and the switches are set as follows. The transistors TRP and TRN are set to an OFF state. The switches S1P and S2P are set to a closed state (or an ON or conductive state), and the switches S1N, S3P, S3N, S4P, and S4N are set to an open state (or an OFF or a cutoff state). Since a circuit at the rear stage connected to the output terminals T3P and T3N has high impedance, the switches S5P and S5N may be in one of the closed and open states.

First, signals DP and DN (hereinafter referred to as reception signals) are input to the input terminals T1P and T1N, respectively. Then, the reception signals are processed by the electrostatic protection circuit, the inductor, and the termination resistor that remove an abnormal voltage such as electrostatic discharge, shape the waveform, and further reduce an effect of reflections, and the processed reception signals reach the nodes N1P and N1N.

The reception signals reaching the nodes N1P and N1N are divided by the resistors R2P and R2N, and a divided signal SIG1 is input to the non-inversion input terminal of the voltage follower VF. A signal SIG2 is output from the output terminal of the voltage follower VF and reaches the node N4.

The signal SIG2 passes through the switch S1P and reaches the node N2P, and is output as an output signal HDP from the output terminal T2P. Simultaneously, the signal SIG2 also passes through the switch S2 and reaches the node N2N, and is output as an output signal HDN from the output terminal T2N.

Accordingly, the output signals HDP and HDN, a voltage difference of which is reduced, can be output from the output terminals T2P and T2N. That is, as the output signals HDP and HDN, a target common voltage with a small voltage difference is supplied to the linear equivalent circuit 33 at the rear stage.

In the above-described embodiment, even when a leakage current occurs in the switches S3P and S3N or a difference in OFF resistance occurs in the switches S3P and S3N due to the reception signals DP and DN, the divided signal SIG1 is amplified using the voltage follower VF. Therefore, as the output signals HDP and HDN, the common voltage with a small voltage difference can be supplied.

Since the signal SIG2 supplied to the output terminal T2P is supplied to the output terminal T2N via the switch S2, a voltage difference between the output signals HDP and HDN can be further reduced.

### 1.2. Advantages in First Embodiment

According to the first embodiment, it is possible to provide the semiconductor integrated circuit capable of improving performance of an operation.

Hereinafter, advantages according to the first embodiment will be described.

In general, for example, in an equalizer in a receiver of an electronic device, offset calibration of a direct-current signal is executed for a stall period in a communication standard (for example, M-PHY standard). When the offset calibration is executed, a data selector inside the equalizer is required to supply a common voltage (an intermediate voltage of a differential signal) for a reception signal to the circuit at the rear stage. However, a target common voltage may not be supplied in some cases.

Accordingly, in the embodiment, an intermediate voltage obtained by dividing a reception signal is output via the voltage follower VF, the output terminal T2P and the output terminal T2N are further connected via the switch S2, and the switch S2 is set to a connection state.

Accordingly, a decrease in the common voltage due to a leakage current occurring in the switch S3P is reduced by using the voltage follower VF. Further, a voltage difference between common voltages output from the output terminal T2P and the output terminal T2N is reduced as much as possible by connecting the output terminal T2P and the output terminal T2N with the switch S2. Accordingly, the data selector 32 inside the equalizer 30 can supply a target common voltage to the circuit at the rear stage. As a result, it is possible to improve performance of an operation of the semiconductor integrated circuit including the equalizer.

### 2. Second Embodiment

A semiconductor integrated circuit according to a second embodiment will be described. In the second embodiment, control of the switch S3N in the data selector 32 inside the equalizer 30 is changed in addition to the configurations of the first embodiment. Other configurations are similar to those of the first embodiment, and differences from the first embodiment will be mainly described in the second embodiment.

### 2.1. Configuration in Second Embodiment

### 2.1.1. Equalizer

The equalizer 30 serving as the semiconductor integrated circuit according to the second embodiment will be described. Configurations of the shaping protection circuit 31 and the data selector 32 inside the equalizer 30 in the second embodiment are similar to the configurations illustrated in FIG. 4.

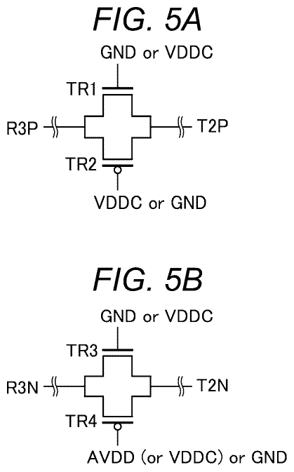

Examples of configurations of the switches S3P and S3N inside the data selector 32 according to the second embodiment will be described with reference to FIGS. 5A and 5B. FIGS. 5A and 5B are circuit diagrams illustrating configurations of the switches S3P and S3N inside the data selector 32. FIG. 5A illustrates a configuration of the switch S3P and FIG. 5B illustrates a configuration of the switch S3N.

As illustrated in FIG. 5A, the switch S3P includes two MOS field effect transistors TR1 and TR2. The transistors TR1 and TR2 configure a transfer gate. The transistor TR1 is, for example, an n-channel MOS field effect transistor. The transistor TR2 is, for example, a p-channel MOS field effect transistor. In the transistors TR1 and TR2, one ends of current passages are connected to each other and the other ends of the current passages are connected to each other.

The supply voltage VDDC or the ground voltage GND (for example, 0 V) is supplied to a gate of the transistor TR1. When the transistor TR1 is set to an ON state, the supply voltage VDDC is supplied to the gate of the transistor TR1. Conversely, when the transistor TR1 is set to an OFF state, the ground voltage GND is supplied to the gate of the transistor TR1. The supply voltage VDDC is supplied as a power supply to the circuit element in the data selector 32.

The supply voltage VDDC or the ground voltage GND is supplied to the gate of the transistor TR2. When the transistor TR2 is set to an ON state, the ground voltage GND is supplied to the gate of the transistor TR2. Conversely, when the transistor TR2 is set to the OFF state, the supply voltage VDDC is supplied to the gate of the transistor TR2.

As illustrated in FIG. 5B, the switch S3N includes two MOS field effect transistors TR3 and TR4. The transistors TR3 and TR4 configure a transfer gate. The transistor TR3 is, for example, an n-channel MOS field effect transistor. The transistor TR4 is, for example, a p-channel MOS field effect transistor. In the transistors TR3 and TR4, one ends of current passages are connected to each other and the other ends of the current passages are connected to each other.

The supply voltage VDDC or the ground voltage GND is supplied to a gate of the transistor TR3. When the transistor TR3 is set to an ON state, the supply voltage VDDC is supplied to the gate of the transistor TR3. Conversely, when the transistor TR3 is set to an OFF state, the ground voltage GND is supplied to the gate of the transistor TR3.

A supply voltage AVDD (or the supply voltage VDDC) or the ground voltage GND is supplied to the gate of the transistor TR4. When the transistor TR4 is set to an ON state, the ground voltage GND is supplied to the gate of the transistor TR4. Conversely, when the transistor TR4 is set to the OFF state, the supply voltage AVDD (or the supply voltage VDDC) is supplied to the gate of the transistor TR4. The supply voltage AVDD is a voltage higher than the supply voltage VDDC.

When the offset calibration is executed in the embodiment, the switch S3N is set to the open state. That is, the transistors TR3 and TR4 are set to the OFF state. When the transistors TR3 and TR4 are set to the OFF state, the ground voltage GND is supplied to the gate of the transistor TR3 and the supply voltage AVDD is supplied to the gate of the transistor TR4.

In the first embodiment, the supply voltage VDDC is supplied to the gate of the transistor TR2. In the second embodiment, however, the supply voltage AVDD is supplied to the gate of the transistor TR4. Therefore, OFF resistance of the transistor TR4 (or the switch S3N) can be set to be higher than OFF resistance of the transistor TR2 (or the switch S3P) in the first embodiment. Accordingly, a leakage current occurring in the switch S3N can be reduced. As a result, a voltage difference between the signals HDP and HDN output from the data selector 32 can be reduced, and thus a target common voltage can be supplied to a circuit at the rear stage.

### 2.2. Advantages in Second Embodiment

According to the second embodiment, the following advantages are obtained in addition to the configurations of the above-described first embodiment.

In the embodiment, when the offset calibration is executed, the supply voltage AVDD higher than the supply voltage VDDC applied in a normal communication mode is applied to the gate of the transistor TR4 inside the switch S3N. Accordingly, a leakage current occurring in the switch S3N is reduced by increasing the OFF resistance of the switch S3N. Accordingly, it is possible to further reduce a voltage difference between the common voltages output from the output terminal T2P and the output terminal T2N. Accordingly, the data selector 32 inside the equalizer 30 can supply the target common voltage to the circuit at the rear stage. As a result, it is possible to improve performance of an operation of the semiconductor integrated circuit including the equalizer.

In the above-described embodiment, the host interface in the memory controller controlling the semiconductor memory (for example, the NAND flash memory) is described as an example. The embodiment is not limited to the interface in the memory controller and can be applied to an interface in another device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor integrated circuit comprising:
a first transmission line;
a first switch connected between a first node and a second node in the first transmission line;
a second transmission line;
a second switch connected between a third node and a fourth node in the second transmission line;
a voltage follower including an inversion input terminal, a non-inversion input terminal, and an output terminal;
a first resistor connected between the non-inversion input terminal of the voltage follower and the first node;
a second resistor connected between the non-inversion input terminal of the voltage follower and the third node;
a third switch connected between the output terminal of the voltage follower and the second node;
a fourth switch connected between the output terminal of the voltage follower and the fourth node; and
a fifth switch connected between the second node and the fourth node.

2. The semiconductor integrated circuit according to claim 1, wherein
the first switch includes a first p-channel MOS field effect transistor (pMOSFET),
the second switch includes a second pMOSFET,
the first switch and the second switch are set to an open state,
a first voltage is supplied to a gate of the first pMOSFET, and
a second voltage higher than the first voltage is supplied to a gate of the second pMOSFET.

3. The semiconductor integrated circuit according to claim 1, wherein
the first switch includes a first n-channel MOS field effect transistor (nMOSFET) and a first p-channel MOS field effect transistor (pMOSFET),
the second switch includes a second nMOSFET and a second pMOSFET,
a first end of a current passage of the first nMOSFET is connected to a first end of a current passage of the first pMOSFET, and a second end of the current passage of the first nMOSFET is connected to a second end of the current passage of the first pMOSFET, and
a first end of a current passage of the second nMOSFET is connected to a first end of a current passage of the second pMOSFET, and a second end of the current passage of the second nMOSFET is connected to a second end of the current passage of the second pMOSFET.

4. The semiconductor integrated circuit according to claim 3, wherein
the first switch and the second switch are set to an open state,
a first voltage is supplied to a gate of the first pMOSFET,
a second voltage higher than the first voltage is supplied to a gate of the second pMOSFET, and
a ground voltage is supplied to the gates of the first nMOSFET and the second nMOSFET.

5. The semiconductor integrated circuit according to claim 1, wherein
the first switch and the second switch each include a transistor, and
when the transistor is set to an off state, off resistance of the second switch is higher than off resistance of the first switch.

6. A method of executing offset calibration of a direct-current (DC) signal for a stall period in a communication standard in the semiconductor integrated circuit according to claim 1, the method comprising:
inputting a first voltage to the first transmission line;
inputting a second voltage higher than the first voltage to the second transmission line;
setting the first switch, the second switch, and the fourth switch to an open state; and
setting the third switch and the fifth switch to a closed state.

7. The method according to claim 6, wherein the communication standard includes an M-PHY standard.

8. A method of executing offset calibration in the semiconductor integrated circuit according to claim 1, the method comprising:
inputting a first voltage to the first transmission line;
inputting a second voltage to the second transmission line;
outputting an intermediate voltage between the first voltage and the second voltage from the first transmission line and the second transmission line;
setting the first switch, the second switch, and the fourth switch an open state; and
setting the third switch and the fifth switch to a closed state.

9. The semiconductor integrated circuit according to

1. wherein the first resistor and the second resistor have an identical resistant value.

10. The semiconductor integrated circuit according to claim 1, further comprising:
a linear equivalent circuit configured to receive signals output from the first and second transmission lines; and
a variable gain amplifier circuit configured to receive a signal output from the linear equivalent circuit.

11. The semiconductor integrated circuit according to claim 10, further comprising:
a buffer circuit configured to receive a signal output from the variable gain amplifier.

12. The semiconductor integrated circuit according to claim 10, wherein
the linear equivalent circuit is configured to compensate for attenuation of a frequency response occurring in a transmission line.

13. The semiconductor integrated circuit according to claim 10, wherein
the variable gain amplifier circuit is configured to adjust a gain and amplify a level of an input signal in accordance with characteristics of a transmission line or a frequency or intensity of a signal.

14. The semiconductor integrated circuit according to claim 1, further comprising:
a first input terminal electrically connected to the first node of the first transmission line;
a second input terminal electrically connected to the third node of the second transmission line;
a first inductor connected between the first input terminal and the first node;
a second inductor connected between the second input terminal and the third node; and
a third inductor connected between the first node and the third node.

15. The semiconductor integrated circuit according to claim 1, further comprising:
a first input terminal electrically connected to the first node of the first transmission line;
a second input terminal electrically connected to the third node of the second transmission line;
a first electrostatic protection circuit connected between the first input terminal and the first node; and
a second electrostatic protection circuit connected between the second input terminal and the third node.

16. The semiconductor integrated circuit according to claim 15, wherein
the first electrostatic protection circuit includes a first diode and a second diode,
an anode of the first diode is electrically connected to the first input terminal, and a cathode of the first diode is electrically connected to a supply voltage end,
an anode of the second diode is electrically connected to a ground voltage end, and a cathode of the second diode is electrically connected to the first input terminal,
the second electrostatic protection circuit includes a third diode and a fourth diode,
an anode of the third diode is electrically connected to the second input terminal, and a cathode of the third diode is electrically connected to the supply voltage end, and
an anode of the fourth diode is electrically connected to the ground voltage end and a cathode of the fourth diode is electrically connected to the second input terminal.

17. The semiconductor integrated circuit according to claim 1, further comprising:
a first input terminal electrically connected to the first node of the first transmission line;
a second input terminal electrically connected to the third node of the second transmission line;
a first resistor connected between the first input terminal and the first switch;
a second resistor connected between the second input terminal and the second switch; and
a third resistor connected between the first node and the third node.

18. The semiconductor integrated circuit according to claim 1, wherein
the voltage follower includes an arithmetic amplifier, and
the output terminal is connected to the inversion input terminal.

19. A semiconductor storage device comprising:
the semiconductor integrated circuit according to claim 1; and
a nonvolatile memory configured to store data in a nonvolatile manner.

20. The semiconductor storage device according to claim 19, wherein the nonvolatile memory includes a NAND flash memory in which memory cells are arranged in a 3-dimensional array.
